(19) United States
(12) Patent Application Publication
(10) Pub. No.: US 2014/0361917 A1
(43) Pub. Date: Dec. 11, 2014

(54) COMPARING CIRCUIT AND A/D CONVERTER

(71) Applicant: KABUSHIKI KAISHA TOSHIBA, Tokyo (JP)

(72) Inventors: Junya MATSUNO, Kawasaki-Shi (JP); Masanori FURUTA, Odawara-Shi (JP); Tetsuro ITAKURA, Tokyo (JP)

(21) Appl. No.: 14/297,343

(22) Filed: Jun. 5, 2014

(30) Foreign Application Priority Data
Jun. 11, 2013 (JP) 2013-122815

(51) Int. Cl. G01R 19/00; G01R 19/10; H03M 1/12

(52) U.S. Cl. CPC G01R 19/0038; H03M 1/12; G01R 19/10
USPC 341/155; 327/50

(57) ABSTRACT

The first amplifier operates according a first clock, changes voltages of a first terminal and a second terminal from a first fixed voltage to a second fixed voltage according to a voltage of an input signal and a first reference voltage, respectively, when an on period of a first clock starts, and keeps the voltages of the first and second terminals at the second fixed voltage, respectively, after the voltages of the first and second terminals reach the second fixed voltage and until the on period of the first clock ends, and the first comparator generates first and second logic signals that have logical levels different from each other, based on a difference between the voltages of the first and second terminals when the on period of a second clock whose on period at least partially overlaps with that of the first clock starts.

### CROSS-REFERENCE TO RELATED APPLICATIONS

This application is based upon and claims the benefit of priority from Japanese Patent Application No. 2013-122815, filed Jun. 11, 2013; the entire contents of which are incorporated herein by reference.

### FIELD

Embodiments described herein relate to a comparing circuit and an A/D converter.

### BACKGROUND

In a conventional comparing circuit, an amplifier in a first stage amplifies a difference between a fixed voltage and an input voltage, and provides differential outputs to an amplifier (comparator) in a following stage. At this point, since one of the differential outputs from the amplifier in the first stage is kept at a high level, an inputting transistor of the amplifier in the following stage is not turned off, which causes leakage current and discharge current to flow.

Furthermore, in another conventional comparing circuit (double-tail circuit), two outputting terminals of a comparator in a following stage are each connected to a ground via two types of transistor switches. A transistor switch of one of the types is turned on/off depending on an input voltage from an amplifier in a preceding stage. A transistor switch of the other type is turned on/off depending on output voltages of the comparator. Since one of the output voltages converges to a high level while a clock is at a high level, leakage current and discharge current flow via the transistor of the other type. As a result, power consumption is increased.

### BRIEF DESCRIPTION OF THE DRAWINGS

FIG. 1 is a block diagram of a comparing circuit according to a first embodiment;

FIG. 2 is an operation chart of the comparing circuit shown in FIG. 1;

FIG. 3 is a block diagram of an amplifier according to the first embodiment;

FIG. 4 is a block diagram of a comparator according to the first embodiment;

FIG. 5 is a block diagram of an interpolating comparator according to the first embodiment;

FIG. 6 is a configuration diagram of a specific example of the amplifier shown in FIG. 3;

FIG. 7 is a configuration diagram of a specific example of the comparator shown in FIG. 4;

FIG. 8 is a configuration diagram of a specific example of the interpolating comparator shown in FIG. 5;

FIG. 9 is a block diagram of a comparing circuit according to a second embodiment;

FIG. 10 is a block diagram of an A/D converter according to a third embodiment;

FIG. 11 is a diagram showing examples of output waveforms of the amplifiers and the interpolating comparator according to the first embodiment; and

FIG. 12 is a diagram showing one state of a circuit of the interpolating comparator according to the first embodiment.

### DETAILED DESCRIPTION

According to one embodiment, there is provided a comparing circuit including a first amplifier and a first comparator.

The first amplifier operates according to a first clock, changes a voltage of a first terminal from a first fixed voltage to a second fixed voltage according to a voltage of an input signal and changes a voltage of a second terminal from the first fixed voltage to the second fixed voltage according to a first reference voltage when an on period of the first clock starts, and keeps each of the voltages of the first and second terminals at the second fixed voltage after the voltages of the first and second terminals reach the second fixed voltage and until the on period of the first clock ends.

The first comparators operates according to a second clock whose on period at least partially overlaps with that of the first clock, and generates first and second logic signals that have logical levels different from each other, based on a first difference voltage being a difference between the voltages of the first and second terminals when the on period of the second clock starts.

Hereinafter, the present embodiments will be described below with reference to the drawings.

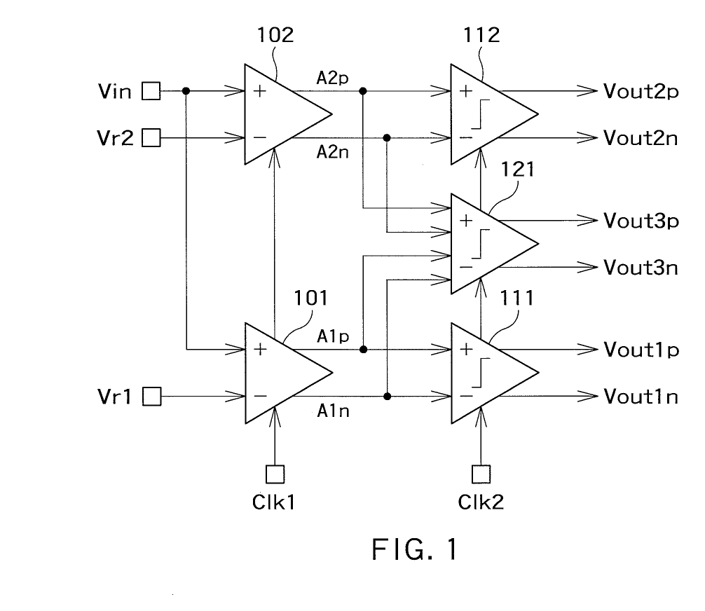

FIG. 1 is a block diagram of a comparing circuit according to a first embodiment.

This comparing circuit is a comparing circuit that is mounted on, for example, a parallel (Flash type) A/D converter.

This comparing circuit includes an amplifier (first amplifier) 101, an amplifier (second amplifier) 102, a comparator (first comparator) 111, a comparator (second comparator) 112, and a comparator (third comparator) 121. This comparing circuit further includes terminals Vin, Vr2, Vr1, Clk1, and Clk2. One of the features of the present embodiment is to reduce leakage currents and discharge currents from the comparators 111, 112, and 121. Here, the leakage current means current that flows from a power supply voltage Vdd to a ground GND, and the discharge current means current that flows from an outputting terminal (capacitance) to the ground.

The terminals Vr1 and Vr2 receive a reference voltage (first reference voltage) Vr1 and a reference voltage (second reference voltage) Vr2, respectively. The terminal Vin receives an input signal Vin to be subjected to A/D conversion. The input signal Vin is obtained by, for example, sampling an analog signal. Vr2 and Vr1 are voltages each representing, for example, an input range of the input signal, and satisfying Vr2>Vr1. Vr2 and Vr1 can be obtained through any methods such as resistance division and capacitance division. The terminal Clk1 receives a clock Clk1 that is an operation clock for the amplifiers 101 and 102. The terminal Clk2 receives a clock Clk2 that is an operation clock for the comparators 111, 121, and 112.

The amplifier 101 receives the input voltage Vin and the reference voltage Vr1. The amplifier 101 amplifies and outputs a difference between Vin and Vr1 while the clock Clk1 is at a high level (hereinafter, referred to as High).

The amplifier 102 receives the input voltage Vin and the reference voltage Vr2. The amplifier 102 amplifies and outputs a difference between Vin and Vr2 while the clock Clk1 is High.

The comparator 111 generates and outputs logic signals Vout1p and Vout1n that have logical levels different from each other, based on the difference output of the amplifier 101, while the clock Clk2 is High. One of Vout1p and Vout1n is High, and the other is at a low level (hereinafter, referred to as Low).

The comparator 112 generates and outputs logic signals Vout2p and Vout2n that have logical levels different from each other, based on the difference output of the amplifier 102, while the clock Clk2 is High. One of Vout2p and Vout2n is High, and the other is Low.

The comparator (interpolating comparator) 121 generates and outputs logic signals Vout3p and Vout3n that have logical levels different from each other, based on a difference between the difference output of the amplifier 101 and the difference output of the amplifier 102. The comparator 121 outputs, with respect to (Vr1+Vr2)/2 that is a value interpolated between the reference voltages Vr1 and Vr2, logic signals Vout3p and Vout3n representing the magnitude relation between Vin and (Vr1+Vr2)/2. One of Vout3p and Vout3n is High, and the other is Low.

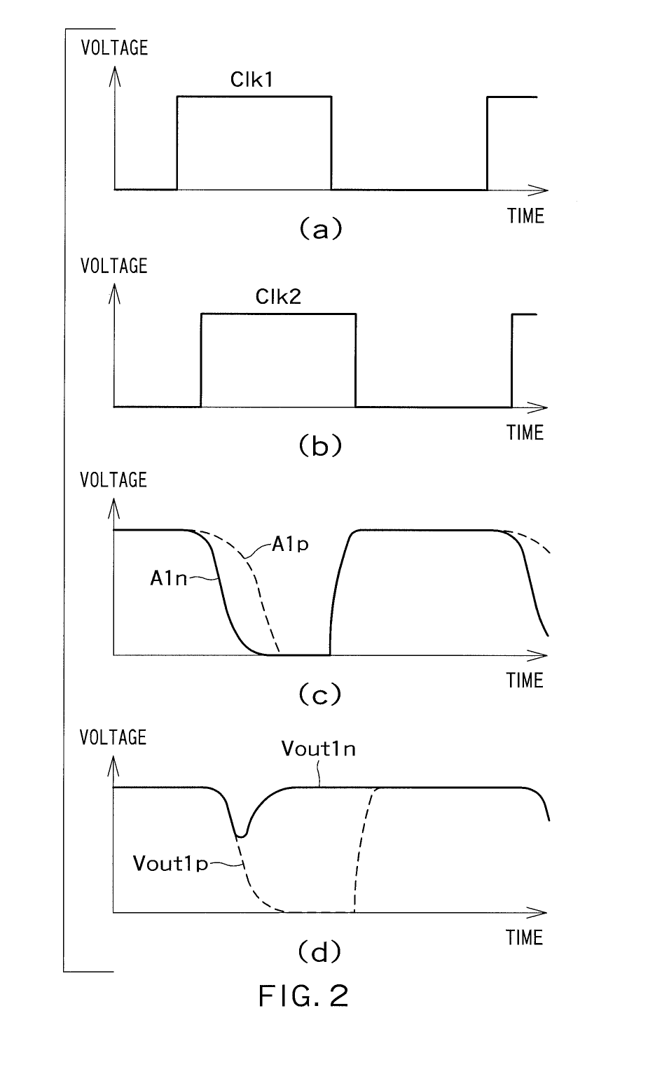

FIG. 2 shows output waveforms from the amplifier 101 and the comparator 111 in the circuit shown in FIG. 1, and waveforms of the clocks Clk1 and Clk2.

FIG. 2(A) shows the waveform of the clock Clk1 input into the amplifier 101. A period from a rising edge to a falling edge of the waveform is an on period of the clock. FIG. 2(C) shows the output waveform of the amplifier 101 when the input signal Vin satisfying Vin>Vr1 is input into the circuit of FIG. 1.

While the clock Clk1 is OFF, both outputs (A1p and A1n) of the amplifier 101 are at a power supply voltage Vdd (High). When the clock Clk1 becomes ON, the amplifier 101 starts operating. During the operation, the voltages A1n and A1p of the outputting terminals drop from Vdd according to Vin1 and Vr1, respectively, with the passage of time. The voltage of the outputting terminal A1n drops from Vdd according to the voltage Vin that is input into a positive terminal of the amplifier 101 shown in FIG. 1, and converges to the ground. In addition, the voltage of the outputting terminal A1p drops from Vdd according to the voltage Vr1 that is input into a negative terminal thereof, and converges to the ground. Since Vin>Vr1 is satisfied, the voltage of the outputting terminal A1n drops faster than that of the outputting terminal A1p, which causes a difference between both of the voltages. A comparator in a following stage generates the logic signals representing the magnitude relation between Vin and Vr1 by making use of the difference. Eventually, at a point in time before the end of the on period of the clock Clk1, the outputs A1n and A1p both converge to the ground and the difference therebetween becomes zero. In such a manner, since the outputs A1n and A1p both converge to Low (ground) in the middle of the on period of the clock, the High voltage is not thereafter input into the comparator 111 in the following stage, until the end of the on period. As a result, in the comparator 111, leakage current and discharge current do not flow after the outputs A1n and A1p converge to the ground, which can reduce the power consumption of the comparator 111.

FIG. 2(B) shows the clock Clk2 that is input into the comparator 111 in the following stage. FIG. 2(D) shows the output waveform of the comparator 111 when the input signal Vin satisfying Vin>Vr1 is input into the circuit of FIG. 1.

With taking a delay from inputting the clock Clk1 into the amplifier 101 to obtaining the output from the amplifier 101 into account, a timing (rising edge) of the clock Clk2 is slightly delayed with respect to the clock Clk1. Both of Clk1 and Clk2 have the same cycle of the clock. The comparator 111 generates logical level signals Vout1p and Vout1n based on a difference between A1p and A1n that are input from the amplifier 101. While the clock Clk2 is not input, Vout1p and Vout1n are both High. The comparator 111 generates the logical level signals Vout1p and Vout1n based on the difference between A1p and A1n by making use of a signal of the difference between A1p and A1n before converging to the ground, and maintains the signal with an internal latch circuit. Even when A1p and A1n converge and the difference thereof becomes zero, the logical level signals Vout1p and Vout1n are maintained by the latch circuit. In FIG. 2(D), Vout1n is High, and Vout1p is Low. This logical state indicates Vin>Vr1.

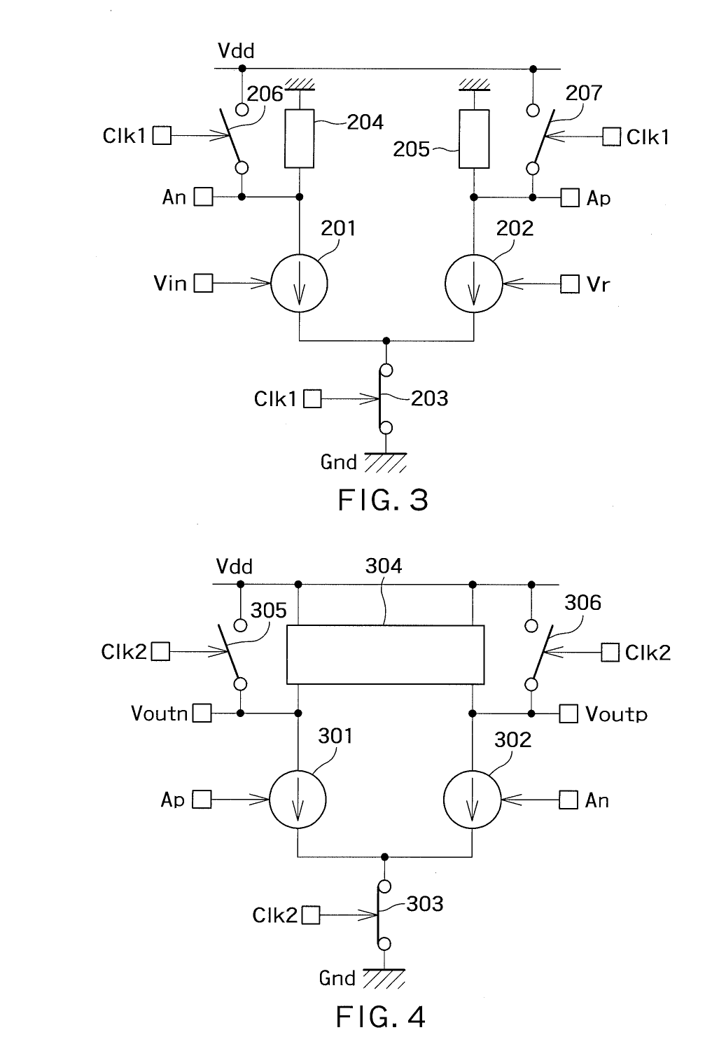

FIG. 3 is a block diagram of the amplifiers 101 and 102. Since the amplifiers 101 and 102 have the same configuration, only the configuration of one of the amplifiers is shown here.

A switch 206 is connected between a power supply voltage terminal (also simply referred to as a power supply voltage) Vdd and the outputting terminal An. The on/off of the switch 206 is controlled by the clock Clk1. An element 204 is connected between Gnd and the outputting terminal An.

A switch 207 is connected between the power supply voltage Vdd and the outputting terminal Ap. The on/off of the switch 207 is controlled by the clock Clk1. An element 205 is connected between Gnd and the outputting terminal Ap.

A voltage-controlled current source (hereinafter, a current source) 201 is connected to the element 204 in series. The current source 201 is connected to a ground terminal (also simply referred to as a ground) via a switch 203. Likewise, a current source 202 is connected to the element 205 in series. The current source 202 is connected to the ground via the switch 203. The on/off of the switch 203 is controlled by the clock Clk1.

When the clock Clk1 is High, the switch 203 is turned on, and when the clock Clk1 is Low, the switch 203 is turned off. Meanwhile, the switches 206 and 207 operate in a manner complementary thereto. That is, when the clock Clk1 is High, the switches 206 and 207 are turned off, and when the clock Clk1 is Low, the switches 206 and 207 are turned on.

The elements 204 and 205 are capacitors or parasitic capacitors. As the parasitic capacitors, parasitic capacitances added to the outputting terminals (nodes) An and Ap can be used. In this case, the elements 204 and 205 are not present as actual elements. Note that, as the elements 204 and 205, elements that have very high impedances for DC (direct current), or very large resistor elements can be used, instead of capacitors.

The current source 201 draws a current from the capacitor 204 according to the input voltage Vin while the switch 203 is turned on, and the current source 202 draws a current from the capacitor 205 according to the reference voltage Vr (Vr1 or Vr2). While the switch 203 is turned off, the capacitors 204 and 205 accumulate electric charges, and when the switch 203 is turned on, the current sources 201 and 202 draw these electric charges. The current sources 201 and 202 pass more currents as the values of the voltages applied thereto are higher. In such a manner, the electric charges accumulated in the capacitors while the clock is OFF (i.e., while the switch 203 is turned off and the switches 206 and 207 are turned on) are drained to the ground by the current sources 201 and 202 at speeds depending on the voltages applied thereto, while the clock is ON (while the switch 203 is turned on and the switches 206 and 207 are turned off). As a result, a voltage difference is generated between the outputting terminals An and Ap according to a difference between the speeds. Since the elements 204 and 205 are capacitors, the voltages of the outputting terminals An and Ap eventually become the ground, and the voltage difference of the outputting terminals An and Ap becomes zero. Note that, when the clock Clk1 is OFF, the switches 206 and 207 are turned on and the switch 203 is turned off, and the voltages of the outputting terminals An and Ap are therefore at Vdd.

In the first related art, a latch circuit is provided instead of the elements 204 and 205. Thus, there is a problem in which the output An or Ap is kept High while the clock Clk1 is ON, and leakage current and discharge current keep flowing from a comparator in a following stage. In contrast, with the above configuration, since the outputs An and Ap converge to the ground in the middle of the on period of the clock Clk1, no or reduced leakage current and discharge current flow from the comparator in the following stage, after the convergence. This can make the comparator consume less power consumption.

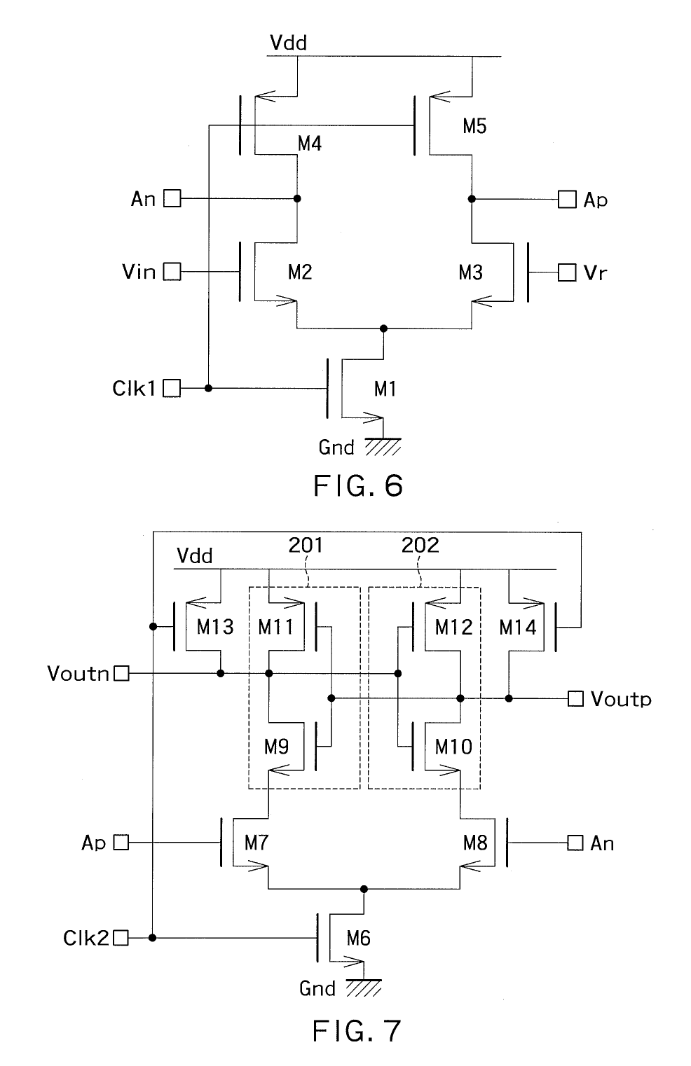

FIG. 6 shows a more specific configuration example of the amplifiers 101 and 102.

The switch 203 shown in FIG. 3 is configured by an NMOS transistor M1. The current sources 201 and 202 are configured by NMOS transistors M2 and M3, respectively. The switches 206 and 207 are configured by PMOS transistors M4 and M5, respectively.

The clock Clk1 is applied to gate terminals (control terminals) of the NMOS transistor M1 and the PMOS transistors N14 and M5. The input voltage Vin is applied to a gate terminal of the NMOS transistor M2, and the reference voltage Vr (Vr1 or Vr2) is applied to a gate terminal of the NMOS transistor M3. The outputting terminal An is connected to a connecting point of a drain terminal of the NMOS transistor M2 and a drain terminal of the PMOS transistor M4. The outputting terminal Ap is connected to a connecting point of a drain terminal of the NMOS transistor M3 and a drain terminal of the PMOS transistor M5.

In the configuration example of FIG. 6, the parasitic capacitances added to the outputting terminals (nodes) An and Ap are used as the elements 204 and 205 shown in FIG. 3, which are therefore not shown as elements in the circuit diagram. If actual capacitive elements are used, one end of the capacitive element 204 may be connected to Gnd and the other end thereof may be connected to the outputting terminal An, and in addition, one end of the capacitive element 205 may be connected to Gnd and the other end thereof may be connected to the outputting terminal Ap.

FIG. 4 is a block diagram of the comparators 111 and 112 shown in FIG. 1. Since the comparators 111 and 112 have the same configuration, only the configuration of one of the comparators is shown here.

A switch 305 is connected between the power supply voltage Vdd and the outputting terminal Voutn (Vout1n or Vout2n). A switch 306 is connected between the power supply voltage Vdd and the outputting terminal Voutp (Vout1p or Vout2p). The on/off of the switches 305 and 306 is controlled by the clock Clk2. In addition, a latch circuit 304 is connected between the power supply voltage Vdd and the outputting terminals Voutn and Voutp.

One end of a current source 301 is connected to the outputting terminal Voutn, and the other end thereof is connected to the ground Gnd via a switch 303. One end of a current source 302 is connected to the outputting terminal Voutp, and the other end thereof is connected to the ground Gnd via the switch 303.

The on/off of the switch 303 is controlled by the clock Clk2. When the clock Clk2 is High, the switch 303 is turned on, and when the clock Clk2 is Low, the switch 303 is turned off. Conversely, the switches 305 and 306 are turned off when the clock Clk2 is High, and are turned on when the clock Clk2 is Low.

The current source 301 operates so as to, when the clock Clk2 is High (when the switch 303 is turned on), pass a current from Vdd via the latch circuit 304 according to the input voltage Ap (A1p or A2p). The current source 302 operates so as to, when the clock Clk2 is High (when the switch 303 is turned on), pass a current from Vdd via the latch circuit 304 according to the input voltage An (A1n or A2n).

The latch circuit 304 includes a circuit in which two inverters are connected to each other in series, an output of the one of the inverters is connected to the outputting terminal Voutn, and an output of the other inverter is connected to the outputting terminal Voutp. When the clock Clk2 is High, the latch circuit 304 outputs logic signals to the outputting terminals Voutn and Voutp based on the magnitude relation between the input voltages Ap and An. One of the output voltages Voutn and Voutp is High, and the other thereof is Low. For example, when the input voltage Ap is higher than An, the output voltage Voutp is Low and Voutn is High, and conversely, when the input voltage Ap is lower than An, the output voltage Voutp is High, and Voutn is Low. Note that, when the clock Clk2 is Low, both of the output voltages Voutn and Voutp are High.

FIG. 7 shows a more specific configuration example of the comparators 111 and 112.

The switch 303 shown in FIG. 4 is configured by an NMOS transistor M6. The current sources 301 and 302 are configured by NMOS transistors M7 and M8, respectively. The switches 305 and 306 are configured by PMOS transistors M13 and M14, respectively.

The latch circuit 304 includes an inverter 201 and an inverter 202. The inverter 201 and the inverter 202 are connected to each other in a series loop such that an output of one of the inverters is provided to an input of the other inverter, and an output of the other inverter is provided to an input of the one inverter.

The inverter 201 is configured by connecting a drain terminal of the PMOS transistor M11 to a drain terminal of the NMOS transistor M9, and further connecting gate terminals of both transistors. The inverter 202 is configured by connecting a drain terminal of the PMOS transistor M12 to a drain terminal of the NMOS transistor M10, and further connecting gate terminals of both transistors. The output of the inverter 101 is connected to the Voutn terminal, and the output of the inverter 102 is connected to the Voutp terminal.

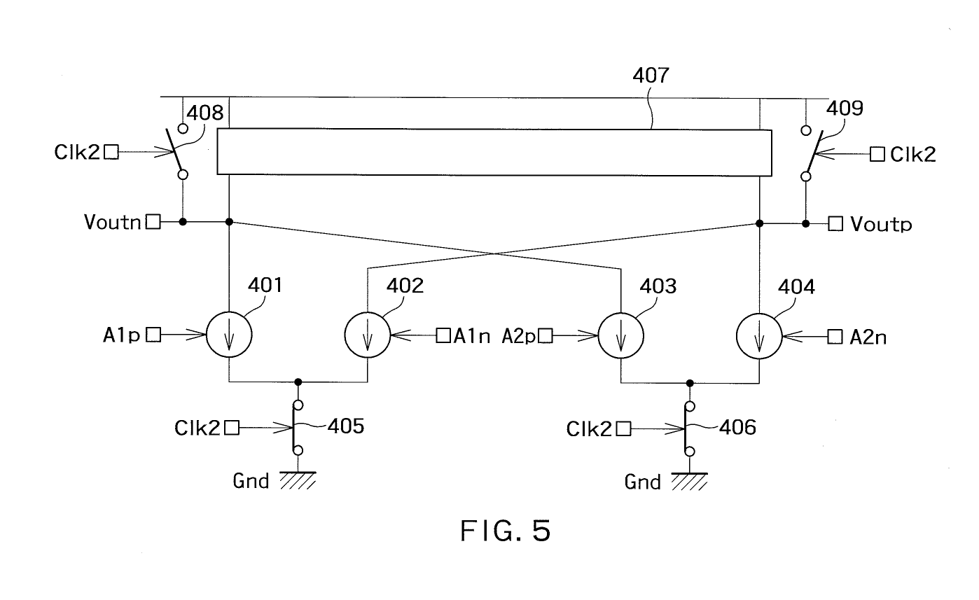

FIG. 5 is a block diagram of the comparator (interpolating comparator) 121 shown in FIG. 1. As compared with the comparators 111 and 112 each having two inputs, the comparator 121 has four inputs (the outputs A1p and A1n of the amplifier 101, and the outputs A2p and A2n of the amplifier 102). The basic operation thereof is the same as that of comparators 111 and 112.

A switch 408 is connected between the power supply voltage Vdd and an outputting terminal Voutn (Vout3n). A switch 409 is connected between the power supply voltage Vdd and an outputting terminal Voutp (Vout3p). The on/off of the switches 408 and 409 is controlled by the clock Clk2. In addition, a latch circuit 407 is connected between the outputting terminals Voutn and Voutp and the power supply voltage Vdd.

One end of a current source 401 is connected to the outputting terminal Voutn, and one end of a current source 402 is connected to the outputting terminal Voutp. The other ends of the current sources 401 and 402 are connected to a ground Gnd via a switch 405.

One end of a current source 403 is connected to the outputting terminal Voutn, and one end of a current source 404 is connected to the outputting terminal Voutp. The other ends of the current sources 403 and 404 are connected to the ground Gnd via a switch 406.

The on/off of the switches 405 and 406 is controlled by the clock Clk2. When the clock Clk2 is High, the switches 405 and 406 are turned on, and when the clock Clk2 is Low, the switches 405 and 406 are turned off. Conversely, when the clock Clk2 is High, the switches 408 and 409 are turned off, and are turned on when the clock Clk2 is Low.

The current source 401 operates so as to, when the clock Clk2 is High (when the switch 405 is turned on), pass a current from Vdd via the latch circuit 407 according to the input voltage A1p. The current source 402 operates so as to, when the clock Clk2 is High (when the switch 405 is turned on), pass a current from Vdd via the latch circuit 407 according to the input voltage A1n. The current source 403 operates so as to, when the clock Clk2 is High (when the switch 406 is turned on), pass a current from Vdd via the latch circuit 407 according to the input voltage A2p. The current source 404 operates so as to, when the clock Clk2 is High (when the switch 406 is turned on), pass a current from Vdd via the latch circuit 407 according to the input voltage A2n.

The latch circuit 407 includes a circuit in which two inverters are connected to each other in series, an output of one of the inverters is connected to the outputting terminal Voutn, and an output of the other inverter is connected to the outputting terminal Voutp. When the clock Clk2 is High, the latch circuit 407 outputs logic signals to the outputting terminals Voutn and Voutp, based on the magnitude relation between the difference between A1p and A2p and the difference between A1n and A2n. One of the output voltages Voutn and Voutp is High, and the other thereof is Low. For example, when the difference between A1p and A2p is greater than the difference between A1n and A2n, the output voltage Voutp is Low, and Voutn is High, and conversely, when the difference between A1p and A2p is smaller than the difference between A1n and A2n, the output voltage Voutp is High, and Voutn is Low. Note that, when the clock Clk2 is Low, both of the output voltages Voutn and Voutp are High.

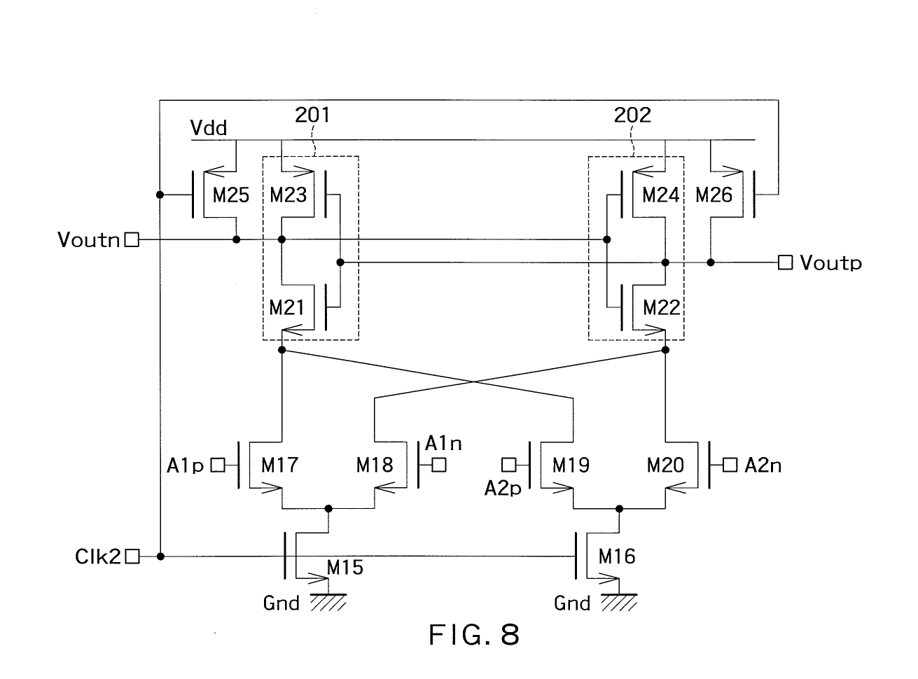

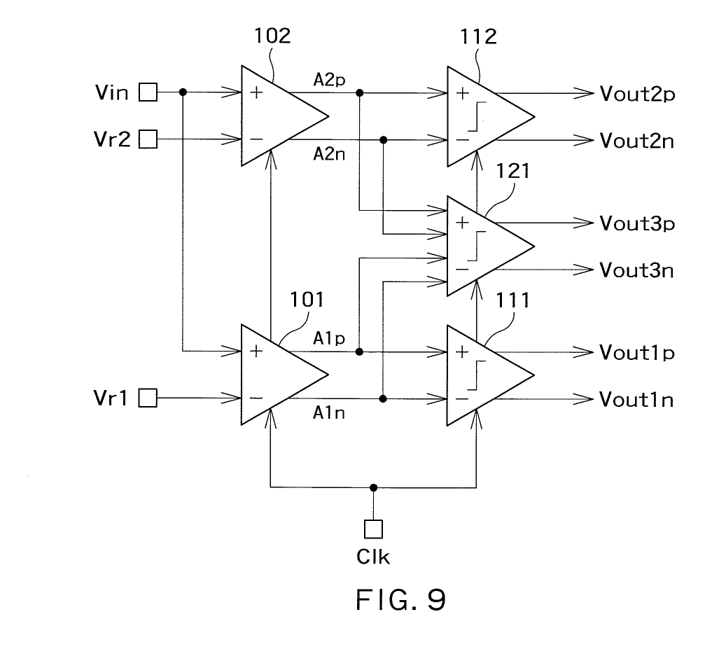

FIG. 8 shows a more specific configuration example of the comparator 121.

The switches 405 and 406 shown in FIG. 5 are configured by NMOS transistors M15 and M16, respectively. The current sources 401, 402, 403, and 404 are configured by NMOS transistors M17, M18, M19, and M20, respectively. The switches 408 and 409 are configured by PMOS transistors M25 and M26, respectively.

The latch circuit 407 includes an inverter 201 and an inverter 202. The inverter 201 and the inverter 202 are connected to each other in a series loop such that an output of one of the inverters is provided to an input of the other inverter, and an output of the other inverter is provided to an input of the one inverter.

The inverter 201 is configured by connecting a drain terminal of the PMOS transistor M23 to a drain terminal of the NMOS transistor M21, and further connecting gate terminals of both transistors. The inverter 202 is configured by connecting a drain terminal of the PMOS transistor M24 to a drain terminal of the NMOS transistor M22, and further connecting gate terminals of both transistors. The output of the inverter 201 is connected to the Voutn terminal, and the output of the inverter 202 is connected to the Voutp terminal.

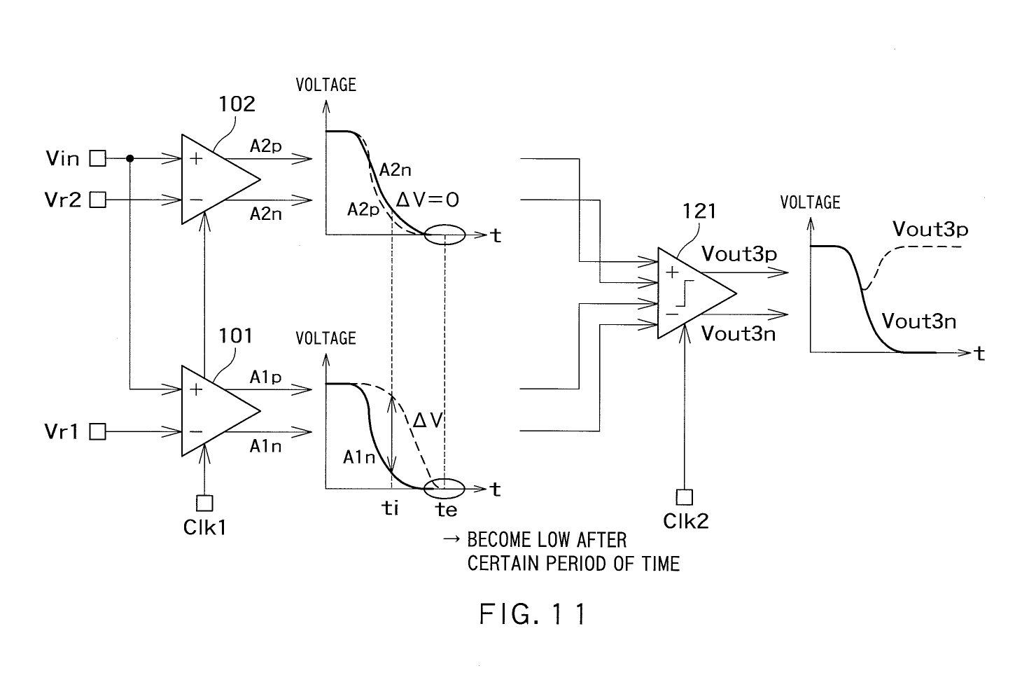

FIG. 11 shows output waveforms of the amplifiers 101 and 102, and the comparator 121 when a signal satisfying′ (Vr1+Vr2)/2<Vin<Vr2 is input into the circuit shown in FIG. 1.

Since Vin>Vr1 is satisfied, between the outputs A1p and A1n of the amplifier 101, Ain drops faster than A1p as with the case shown in FIG. 2(C). At a certain point in time ti after the start of the on period of the Clk1, the difference between the outputs widens to ΔV1. At a point in time te at which a certain period of time has elapsed from the start of the on period of the clock Clk1 (a point in time after ti within a period in which the clock Clk1 is High), both of the outputs converge to Low.

Meanwhile, in the amplifier 102, since Vr2>Vin is satisfied, A2p drops faster than A2n. The output A2p is shown in a dotted line, and A2n is shown in a solid line. A difference between the outputs at the above point in time ti is denoted by ΔV2. Since Vin is higher than (Vr1+Vr2)/2 (i.e., since Vin is a value close to Vr2), the difference between the outputs is small as compared with the amplifier 101. A2n and A2p converge to Low after a certain period of time elapses from the input of the clock Clk1, and both of them converge to Low at the above point in time te. As a result, after the point in time te, all of the outputs from the amplifiers 101 and 102 to a following stage are Low.

The comparator 121 amplifies a difference between the output ΔV1 of the amplifier 101 and the output ΔV2 of the amplifier 102 at the point in time ti (a point in time after a certain period of time is delayed from a rising edge of the clock Clk2). Vout3p is High, and Vout3n is Low. These indicate that Vin is higher than (Vr1+Vr2)/2 and lower than Vr2.

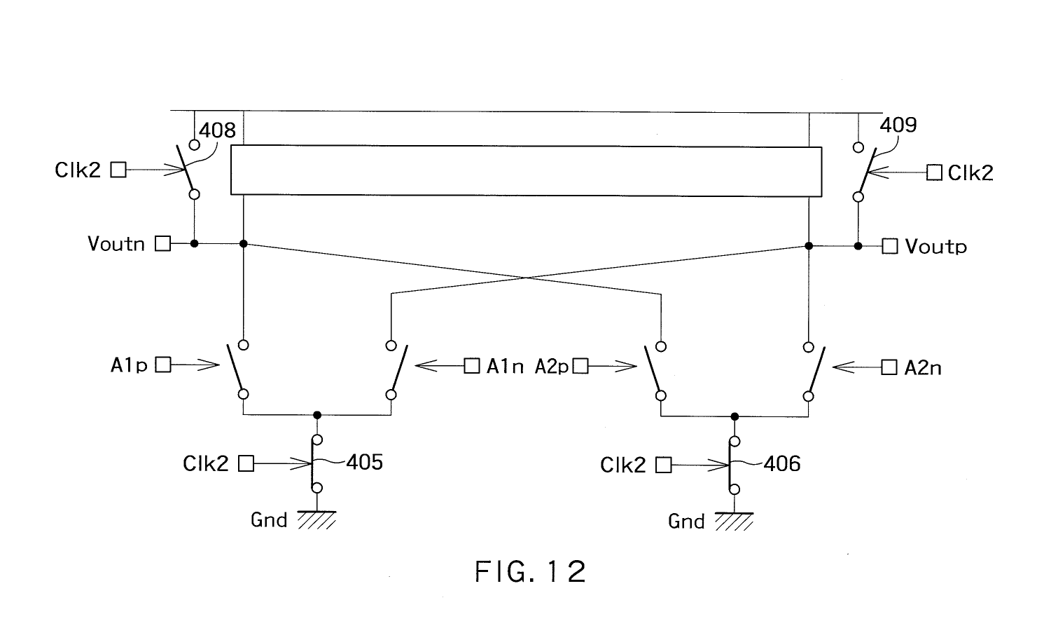

FIG. 12 is a block diagram showing a state of a circuit of the comparator 121 after all of the outputs A1p and A1n of the amplifier 101 and the outputs A2p and A2n of the amplifier 102 converge to the ground. In this diagram, the current sources 401-404 of the circuit shown in FIG. 5 are illustrated as switches (transistors), as with FIG. 8.

After the convergence, since all of the input voltages to the current sources (switches) of the comparator 121 are Low, currents from Vdd to Gnd are completely interrupted, and thus, no leakage current and discharge current flow. As a result, during the on period of the clock Clk1, power consumption of the comparator 121 after the outputs of the amplifiers converge to Low and until the end of the clock on period, can be reduced. Although there is described the example in which the power consumption of the comparator 121 can be reduced, the power consumptions of the comparators 111 and 112 can also be reduced.

According to the first related art, as described above, the amplifiers (amplifiers corresponding to the amplifiers 101 and 102) each have a configuration using a latch circuit, and the outputs A1n and A2p of the amplifiers converge to Low, whereas Ap1 and A2n converge to High. As a result, in the comparators (comparators corresponding to the comparator 121, 111, and 112), leakage current and discharge current flow even after the convergence, which increases the power consumption. In contrast, in the present embodiment, since all of the outputs of the amplifiers converge to Low (ground), no or very little leakage current and discharge current flow from the comparators 121, 111, and 112, which can thereby significantly reduce the power consumption.

In addition, according to a second related art, a current source (CS) is connected between a transistor corresponding to the transistor M1 of the amplifier shown in FIG. 6 and a GND terminal. This configuration does not (or hardly) make outputs Low on purpose, by adjusting a current with the current source (CS). This configuration secures a period of time (clock time margin) during which a large differential voltage of the outputs can be obtained. Thus, an increase of a current occurs by leakage current and discharge current. In contrast, in the present embodiment, since the clock time margin does not need to be secured for the clock Clk1 of the amplifier and the clock Clk2 of the comparator, even a uniform clock can be used, as will be described hereafter. As a result, securing the clock time margin by making use of the current source (CS) is dispensed with, whereby power consumption can be reduced.

Furthermore, according to a third related art, in a comparator in a following stage of a comparing circuit (double-tail circuit), an outputting terminal Voutp is connected to a ground via two NMOS transistors (respectively denoted as A and B), and an outputting terminal Voutn is connected to the ground via two NMOS transistors (respectively denoted as C and D). The NMOS transistors A and D perform ON and OFF operations depending on input voltages from an amplifier in a preceding stage. Meanwhile, the NMOS transistors B and C perform the ON and OFF operations depending on output voltages of a comparator. When a clock Clk is High (Clkbar is Low), one of the output voltages Voutp and Voutn converges to High and the other converges to Low, by a latch circuit that is configured by the above NMOS transistors B and C, and the PMOS transistors (respectively denoted as E and F). As a result, a gate terminal of one of the NMOS transistors B and C is kept High, which causes leakage current and discharge current to flow, increasing power consumption.

In contrast, the outputs of comparator of the present embodiment are connected to the ground via only the transistors (refer to M7 and M8 in FIG. 7, or the like) that perform the ON and OFF operations depending on the input voltages. Therefore, when the input voltages into the comparator (voltages input from the preceding stage amplifier) converge to Low, leakage current and discharge current do not flow, which can reduce the power consumption.

Furthermore, a configuration of the third related art needs the clock Clk and the clock Clkbar that is an reverse-phase clock of Clk, and it is difficult to generate an reverse-phase clock signal with high precision for a high-speed application. But in the present embodiment, since the clocks Clk1 and Clk2 whose on periods are at least partially overlapped can be used, or an in-phase and uniform clock can be used as will be described hereafter, the generation of the reverse-phase clock is not needed.

FIG. 9 shows a block diagram of a comparing circuit according to a second embodiment.

The difference from the comparing circuit of FIG. 1 is that the clocks Clk1 and Clk2 are made uniform. The uniform clock Clk is input into the amplifiers 101 and 102, and the comparators 111, 112, and 121.

The outputs of the amplifiers 101 and 102 are output with a certain delay Td after the clock Clk becomes High. Thus, the clock provided to the comparators 111, 112, and 121 in a following stage preferably becomes High after the delay Td elapses, as compared with the clock provided to the amplifiers 101 and 102 in a preceding stage. The delayed clock can be generated based on the clock Clk provided to the amplifiers in the first stage, by using a delaying circuit such as an inverter circuit. However, in the case of a high-speed application, since the amount of delay Td is small, even if the clocks provided to the first stage and the following stage are made uniform, a desired operation can be obtained. Thus, in the present embodiment, the amplifiers 101 and 102, and the comparators 111, 112, and 121 are configured to receive the uniform clock Clk, which can dispense with the delaying circuit, allowing for the simplification of the circuit and the reduction of the power consumption, while the desired operation is obtained.

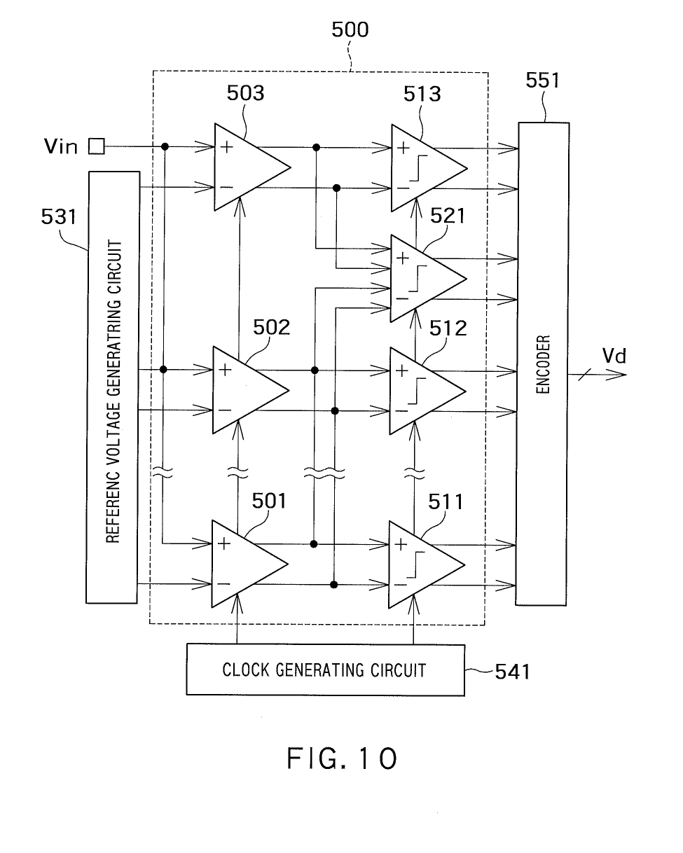

FIG. 10 shows a block diagram of an A/D converter according to a third embodiment.

This A/D converter includes a comparing circuit 500, a reference voltage generating circuit 531, a clock generating circuit 541, and an encoder 551.

The comparing circuit 500 includes three or more amplifiers 501, 502, 503, . . . , and five or more comparators 511, 512, 521, and 513, . . . (note that the illustration of the fifth comparator is omitted). Although in the first embodiment, the number of reference voltages is two, in the present embodiment the number of the reference voltage is increased to three or more, and the numbers of the amplifiers and the comparators are also increased, accordingly. The configurations of the amplifiers and the comparators, and the connections between them can be implemented as with the first embodiment.

The reference voltage generating circuit 531 generates reference voltages to be provided to the amplifiers. The reference voltages may be generated through resistance division, capacitance division, or the like.

The clock generating circuit 541 generates a clock Clk1 to be provided to amplifiers and a clock Clk2 to be provided to comparators. The clock Clk2 may be delayed with respect to the clock Clk1 by a given amount of delay, or both of the clocks may be made uniform as with the second embodiment.

The encoder 551 generates digital data (binary data) based on logic signals (Voutp and Voutn) output from the comparators. That is, the encoder 551 identifies which of sections an input signal is included, the sections into which a voltage range of the input signal is divided, and generates binary data corresponding to the identified section.

Note that, in the foregoing embodiments, although NMOS transistors and PMOS transistors are used for elements such as switches, current sources, and inverter elements, the conductivity types of these transistors can be interchanged. In this case, when an NMOS type transistor that has been connected to GND is replaced with a PMOS transistor, a drain terminal of the replaced PMOS transistor may be connected to Vdd. In addition, when a PMOS transistor that has been connected to Vdd is replaced with an NMOS transistor, a source terminal of the replaced NMOS transistor may be connected to GND

Furthermore, bipolar transistors may be used instead of MOS transistors. In this case, connecting spots of a gate terminal, a source terminal, and a drain terminal of a MOS transistor may be served as connecting spots of a base, an emitter, and a collector of a bipolar transistor, respectively. That is, the gate terminal of the MOS transistor corresponds to the base of the bipolar transistor, the source terminal of the MOS transistor corresponds to the emitter of the bipolar transistor, and the drain terminal of the MOS transistor corresponds to the collector of the bipolar transistor. In the case where the other types of transistors are used, similar measures may be taken.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A comparing circuit comprising:
a first amplifier to operate according to a first clock, to change a voltage of a first terminal from a first fixed voltage to a second fixed voltage according to a voltage of an input signal and to change a voltage of a second terminal from the first fixed voltage to the second fixed voltage according to a first reference voltage when an on period of the first clock starts, and to keep each of the voltages of the first and second terminals at the second fixed voltage after the voltages of the first and second terminals reach the second fixed voltage and until the on period of the first clock ends; and
a first comparator to operate according to a second clock whose on period at least partially overlaps with that of the first clock, and to generate first and second logic signals that have logical levels different from each other, based on a first difference voltage being a difference between the voltages of the first and second terminals when the on period of the second clock starts.

2. The comparing circuit according to claim 1, further comprising:
a second amplifier to operate according to the first clock, to change a voltage of a third terminal from the first fixed voltage to the second fixed voltage according to the voltage of the input signal and to change a voltage of a fourth terminal from the first fixed voltage to the second fixed voltage according to a second reference voltage when the on period of the first clock starts, and to keep each of the voltages of the third and fourth terminals at the second fixed voltage after the voltages of the third and fourth terminals reach the second fixed voltage and until the on period of the first clock ends;
a second comparator to operate according to the second clock, and to generate third and fourth logic signals that have logical levels different from each other, based on a second difference voltage being a difference between the voltages of the third and fourth terminals when the on period of the second clock starts; and
a third comparator to operate according to the second clock, and to generate fifth and sixth logic signals that have logical levels different from each other, based on a difference between the first difference voltage and the second difference voltage when the on period of the second clock starts.

3. The comparing circuit according to claim 1, wherein
the first amplifier includes:
a first voltage-controlled current source to output a current according to the input signal;
a second voltage-controlled current source to output a current according to the first reference voltage;
a first switch to connect between one ends of the first and second voltage-controlled current sources and the second or first fixed voltage;
a second switch connected between the first or second fixed voltage and the other end of the first voltage-controlled current source;
a third switch connected between the first or second fixed voltage and the other end of the second voltage-controlled current source;
the first terminal electrically connected to the other end of the first voltage-controlled current source; and
the second terminal electrically connected to the other end of the second voltage-controlled current source,
the first switch, the second switch, and the third switch operate according to the first clock, and
the first switch operates in a manner complementary to the second switch and the third switch.

4. The comparing circuit according to claim 3, further comprising:
a first capacitive element connected between the second or first fixed voltage and the other end of the first voltage-controlled current source; and
a second capacitive element connected between the second or first fixed voltage and the other end of the second voltage-controlled current source.

5. The comparing circuit according to claim 3, wherein
the first voltage-controlled current source, the second voltage-controlled current source, and the first switch are transistors of a first conductivity type, and
the second switch and the third switch are transistors of a second conductivity type that is complementary to the first conductivity type.

6. The comparing circuit according to claim 5, wherein
the transistors of the first conductivity type are NMOS transistors or PMOS transistors, and
the transistors of the second conductivity type are PMOS transistors or NMOS transistors.

7. The comparing circuit according to claim 1, wherein
the first comparator includes:
a third voltage-controlled current source to output a current according to the voltage of the first terminal;
a fourth voltage-controlled current source to output a current according to the voltage of the second terminal;
a fourth switch to connect between one ends of the third and fourth voltage-controlled current source and the second or first fixed voltage;
a fifth switch connected between the first or second fixed voltage and the other end of the third voltage-controlled current source;
a sixth switch connected between the first or second fixed voltage and the other end of the fourth voltage-controlled current source;
a latch circuit connected between the other ends of the third and fourth voltage-controlled current source, and the first or second fixed voltage;
a fifth terminal electrically connected to the other end of the third voltage-controlled current source, and to output the first logic signal; and
a sixth terminal electrically connected to the other end of the fourth voltage-controlled current source, and to output the second logic signal,
the fourth switch, the fifth switch, and the sixth switch operate according to the second clock,
the fourth switch operates in a manner complementary to the fifth switch and the sixth switch, and
the latch circuit generates voltages that have logical levels different from each other for the fifth terminal and the sixth terminal, based on currents from the third and fourth voltage-controlled current source, respectively.

8. The comparing circuit according to claim 7, wherein
the third and fourth voltage-controlled current source, and the fourth switch are transistors of a first conductivity type,
the fifth switch and the sixth switch are transistors of a second conductivity type that is complementary to the first conductivity type,
the latch circuit includes first and second inverters each having a transistor of the first conductivity type and a transistor of the second conductivity type, one ends of the transistors are connected to each other and control terminals of the transistors are commonly connected, an output of the first inverter is connected to an input of the second inverter, and an output of the second inverter is connected to an input of the first inverter,
in the first inverter, the other end of the transistor of the second conductivity type is connected to the first or second fixed voltage, the other end of the transistor of the first conductivity type is connected to one end of the third voltage-controlled current source, and a connecting part of the first and second conductivity type transistors is electrically connected to the fifth terminal, and
in the second inverter, the other end of the transistor of the second conductivity type is connected to the first or second fixed voltage, the other end of the transistor of the first conductivity type is connected to one end of the fourth voltage-controlled current source, and a connecting part of the first and second conductivity type transistors is electrically connected to the sixth terminal.

9. The comparing circuit according to claim 8, wherein
the transistors of the first conductivity type are NMOS transistors or PMOS transistors, and
the transistors of the second conductivity type are PMOS transistors or NMOS transistors.

10. The comparing circuit according to claim 2, wherein
the third comparator includes:
a fifth voltage-controlled current source to output a current according to a voltage of the first terminal;
a sixth voltage-controlled current source to output a current according to a voltage of the second terminal;
a seventh voltage-controlled current source to output a current according to a voltage of the third terminal;
an eighth voltage-controlled current source to output a current according to a voltage of the fourth terminal;
a seventh switch to connect between one ends of the fifth and sixth voltage-controlled current sources and the second or first fixed voltage;
an eighth switch to connect between one ends of the seventh and eighth voltage-controlled current sources and the second or first fixed voltage;
a ninth switch connected between the other ends of the fifth and seventh voltage-controlled current sources and the first or second fixed voltage;
a tenth switch connected between the other ends of the sixth and eighth voltage-controlled current sources and the first or second fixed voltage;
a latch circuit connected between the first or second fixed voltage and both of a connecting part of the other ends of the fifth and seventh voltage-controlled current sources and a connecting part of the other ends of the sixth and eighth voltage-controlled current sources;
a seventh terminal electrically connected to the other ends of the fifth and seventh voltage-controlled current sources, and to output the fifth logic signal; and
an eighth terminal electrically connected to the other ends of the sixth and eighth voltage-controlled current sources, and to output the sixth logic signal,
the seventh switch, the eighth switch, the ninth switch, and the tenth switch operate according to the second clock,
the seventh switch and the eighth switch operate in a manner complementary to the ninth switch and the tenth switch, and
the latch circuit generates voltages that have logical levels different from each other for the seventh terminal and the eighth terminal, based on a difference between the sum of currents from the fifth and seventh voltage-controlled current sources, and the sum of currents from the eighth and ninth voltage-controlled current sources.

11. The comparing circuit according to claim 10, wherein
the fifth, sixth, seventh, and eighth voltage-controlled current sources, and the seventh and eighth switches are transistors of a first conductivity type,
the ninth switch and the tenth switch are transistors of a second conductivity type that is complementary to the first conductivity type,
the latch circuit includes first and second inverters each having a transistor of the first conductivity type and a transistor of the second conductivity type, one ends of the transistors are connected to each other and control terminals of the transistors are commonly connected, an output of the first inverter is connected to an input of the second inverter, and an output of the second inverter is connected to an input of the first inverter,
in the first inverter, the other end of the transistor of the second conductivity type is connected to the first or second fixed voltage, the other end of the transistor of the first conductivity type is connected to one ends of the fifth and seventh voltage-controlled current sources, and a connecting part of the first and second conductivity type transistors is electrically connected to the seventh terminal,
in the second inverter, the other end of the transistor of the second conductivity type is connected to the first or second fixed voltage, the other end of the transistor of the first conductivity type is connected to one ends of the sixth and eighth voltage-controlled current sources, and a connecting part of the first and second conductivity type transistors is electrically connected to the eighth terminal.

12. The comparing circuit according to claim 11, wherein
the transistors of the first conductivity type are NMOS transistors or PMOS transistors, and
the transistors of the second conductivity type are PMOS transistors or NMOS transistors.

13. The comparing circuit according to claim 1, wherein the second clock and the first clock are same clock.

14. An A/D converter comprising:
the comparing circuit according to claim 1;
a reference voltage generating circuit to generate the first reference voltage,
a clock generating circuit to generate the first and second clocks, and
an encoder to generate digital data based on the first and second logic signals output from the first comparator in the comparing circuit.

15. The A/D converter according to claim 14, wherein
the clock generating circuit generates a single and common clock as the first and second clocks.
